(19) United States
(12) Patent Application Publication
(10) Pub. No.: US 2025/0210939 A1
(43) Pub. Date: Jun. 26, 2025

(54) TEMPERATURE MEASUREMENT IN RIDGE LASER DEVICE

(71) Applicant: ams-OSRAM International GmbH, Regensburg (DE)

(72) Inventors: Bilal SAIF, Regensburg (DE); Jörg Erich SORG, Regensburg (DE)

(73) Assignee: ams-OSRAM International GmbH, Regensburg (DE)

(21) Appl. No.: 18/848,105

(22) PCT Filed: Feb. 1, 2023
(86) PCT No.: PCT/EP2023/052393

§ 371 Date: Sep. 17, 2024

(30) Foreign Application Priority Data
Mar. 24, 2022 (DE) 102022106952.4

(51) Int. Cl. H01S 5/068; H01S 5/026; H01S 5/042; H01S 5/22

(52) U.S. Cl. CPC H01S 5/06804; H01S 5/0262; H01S 5/042; H01S 5/06808; H01S 5/22

(57) ABSTRACT

A laser device is provided, the laser device includes at least one ridge structure that is configured to emit laser radiation, a sense circuitry, a power source, and a current source, wherein the ridge structure has a first side and a second side, the first side is connectable with the power source, the current source and the sense circuitry are connected with each other, and the second side is connectable with the current source and the sense circuitry. Furthermore, a method for operating a laser device is provided.

### CROSS-REFERENCE TO RELATED APPLICATIONS

The present application is a national stage entry from International Application No. PCT/EP2023/052393, filed on Feb. 1, 2023, published as International Publication No. WO 2023/179939 A1 on Sep. 28, 2023, and claims priority to German Patent Application No. 10 2022 106 952.4, filed Mar. 24, 2022, the disclosures of all of which are hereby incorporated by reference in their entireties.

### FIELD

A laser device and a method for operating a laser device are provided.

### BACKGROUND

For laser devices that emit laser radiation during operation, it is necessary to monitor the temperature of the emitting structure. For most applications the temperature of the emitting structure should be within a predefined range for a steady operation of the laser device. Furthermore, it is often necessary to monitor the intensity of emitted laser radiation so that the intensity of emitted laser radiation does not exceed a given threshold value for example for safety reasons. If humans are around, it might be necessary to limit the laser emission to a certain intensity in order to avoid damages to the eyes of humans. It might also be desired to monitor the intensity of emitted laser radiation in order to keep the intensity constant. By monitoring the intensity of emitted laser radiation, the laser device can be controlled in such a way that the threshold value is not crossed. As an example, a photodiode can be employed to monitor emitted laser radiation and a temperature sensor or thermistor can be employed to monitor the temperature.

It is an objective to provide a laser device that has a compact setup. It is further an objective to provide a method for operating a laser device that has a compact setup.

These objectives are achieved by the subject matter of the independent claims. Further developments and embodiments are described in dependent claims.

### SUMMARY

According to at least one embodiment of the laser device, the laser device comprises at least one ridge structure that is configured to emit laser radiation. The ridge structure can comprise a cavity that is arranged between two mirrors. The ridge structure can comprise an active region that is configured to emit electromagnetic radiation during operation of the laser device. The ridge structure can have an elongated shape. This can mean, that the ridge structure has a main extension direction. The ridge structure can form a ridge laser or a ridge waveguide laser. The ridge structure can be configured to emit laser radiation once it is provided with enough power to enable lasing. The ridge structure can be configured to emit radiation through one of the two mirrors adjoining the cavity. The two mirrors can be arranged at opposite sides of the ridge structure along a main extension direction of the ridge structure.

According to at least one embodiment of the laser device, the laser device comprises a sense circuitry. The sense circuitry can be configured to measure a voltage. The sense circuitry can be configured to measure the voltage across the ridge structure. The sense circuitry can comprise sense electronics for analog processing or for digital processing with an analog-to-digital converter (ADC).

According to at least one embodiment of the laser device, the laser device comprises a power source. The power source can be configured to provide power. The power source can be or comprise a driver of the laser device. The power source can be configured to provide the power to the ridge structure that is required to enable lasing. The power source can be configured to provide a current. The power source can be configured to provide a positive current.

According to at least one embodiment of the laser device, the laser device comprises a current source. The current source can be configured to provide a current. The current source can be configured to provide a predefined current. The current source can be configured to provide a negative current.

According to at least one embodiment of the laser device, the ridge structure has a first side and a second side. The first side can be arranged opposite to the second side. The first side can be arranged at one side of the elongated shape of the ridge structure and the second side can be arranged at the opposite side of the elongated shape of the ridge structure. The ridge structure can extend along one straight line. The first side can be arranged at one side of this line and the second side can be arranged at the opposite side of this line.

According to at least one embodiment of the laser device, the first side is connectable with the power source. This can mean that a switch is arranged between the first side and the power source. The first side can be connectable with the power source via a switch. It is also possible that the first side is connected with the power source via a switch. The switch can be a first side switch.

According to at least one embodiment of the laser device, the current source and the sense circuitry are connected with each other. The current source and the sense circuitry can both be connected with a circuit node. This means, the current source and the sense circuitry can both be connected with the same circuit node.

According to at least one embodiment of the laser device, the second side is connectable with the current source and the sense circuitry. This can mean that a switch is arranged between the second side on the one side and the current source and the sense circuitry on the other side. The second side can be connectable with the current source and the sense circuitry via a switch. It is also possible that the second side is connected with the current source and the sense circuitry via a switch. The switch can be a second side switch. The second side can be connectable with the circuit node with which the current source and the sense circuitry are connected via the second side switch. It is also possible that the second side is connected with the circuit node with which the current source and the sense circuitry are connected via the second side switch.

According to at least one embodiment of the laser device, the laser device comprises at least one ridge structure that is configured to emit laser radiation, a sense circuitry, a power source, and a current source, wherein the ridge structure has a first side and a second side, the first side is connectable with the power source, the current source and the sense circuitry are connected with each other, and the second side is connectable with the current source and the sense circuitry.

The laser device has the advantage that the ridge structure can be employed both for the emission of laser radiation and a measurement of the temperature of the ridge structure. For many laser devices it is required to monitor the temperature of the radiation emitting structure. For this purpose, it is common to employ a temperature sensor or thermistor. This additional or external temperature sensor or thermistor is not required in the laser device described herein. Instead, the ridge structure is employed to measure its temperature.

This is achieved by disconnecting the ridge structure from the power source and connecting the ridge structure with the sense circuitry.

Once the first side of the ridge structure is connected with the power source, power can be provided to the ridge structure so that lasing is enabled and the ridge structure emits laser radiation. The second side of the ridge structure is connected with a ground potential in this situation.

For measuring the temperature, the first side is disconnected from the power source and the first side is connected with a ground potential. The second side is connected with the current source and the sense circuitry. For enabling the emission of laser radiation a positive bias is applied to the ridge structure. This means, the ridge structure is operated in forward direction. Once the second side is connected with the current source, a negative current is provided to the ridge structure and the ridge structure is operated in reverse direction. In this situation, the voltage across the ridge structure is proportional to the temperature of the ridge structure. The voltage across the ridge structure is measured by the sense circuitry. Thus, from the voltage measured by the sense circuitry, the temperature of the ridge structure can be determined. After measuring the temperature, the ridge structure can be employed again for the emission of laser radiation. This means, the second side can be disconnected from the current source and the sense circuitry and the first side can be connected again with the power source.

Since no additional device is required for measuring the temperature of the ridge structure, the laser device can have a compact setup.

According to at least one embodiment of the laser device, the sense circuitry is configured to measure a voltage. The sense circuitry can be configured to measure the voltage across the ridge structure. This enables to determine the temperature of the ridge structure which is proportional to the voltage across the ridge structure when supplied with a negative current.

According to at least one embodiment of the laser device, the first side is connectable with the power source via a first side switch. This can mean that between the first side and the power source the first side switch is arranged. The first side can be connected with the power source via the first side switch. By connecting the first side of the ridge structure with the power source, the ridge structure can be provided with power for enabling the emission of laser radiation.

According to at least one embodiment of the laser device, a second side switch is arranged between the second side and a circuit node with which the current source and the sense circuitry are connected. This means, the current source and the sense circuitry are connected with the circuit node. The second side can be connectable or connected with the circuit node via the second side switch. By connecting the second side of the ridge structure with the circuit node, the ridge structure can be provided with a negative current by the current source. This enables to measure a voltage across the ridge structure that is proportional to the temperature of the ridge structure.

According to at least one embodiment of the laser device, the ridge structure comprises a pn-junction whose forward direction is from the first side to the second side. This can mean, if a positive voltage is applied to the first side, the ridge structure is operated in forward direction. This setup enables that the ridge structure is configured to emit laser radiation once it is connected with the power source and that the voltage across the ridge structure once it is connected with the current source relates to the temperature of the ridge structure.

According to at least one embodiment of the laser device, the first side and/or the second side is connectable to a ground potential. This can mean, that the first side switch is arranged between the first side and the ground potential. It is also possible that the second side switch is arranged between the second side and a further ground potential. Via the first side switch the first side can be connected with either the ground potential or the power source. Via the second side switch the second side can be connected with either the circuit node or the further ground potential.

These two connections to ground potentials enable the two different modes of operation of the laser device, namely the emission of laser radiation and the measurement of the temperature of the ridge structure.

According to at least one embodiment of the laser device, the laser device comprises at least one further ridge structure. The further ridge structure can have the same features as the ridge structure. The laser device can thus be a multi-ridge laser device. Between the ridge structure and the further ridge structure a trench can be arranged. The ridge structure and the further ridge structure can be epitaxially grown on the same substrate. The substrate can be transparent or translucent. It is also possible that the ridge structure and the further ridge structure are arranged on a common layer.

The common layer can be transparent or translucent. Laser devices with several ridge structures have the advantages that the dynamic range and the radiation output are increased, that an image resolution can be increased at a given mirror frequency and that the optical complexity is reduced due to the close arrangement of the ridge structures.

The distance between the ridge structure and the further ridge structure can be chosen to be large enough so that a current flow between the ridge structure and the further ridge structure is inhibited. This can mean, that the distance between the ridge structure and the further ridge structure is chosen to be large enough so that no current passes through a pnp junction formed by the ridge structure and the further ridge structure.

The laser device can comprise at least two or at least three ridge structures in total.

The ridge structure can extend parallel to a lateral direction. A main extension direction of the ridge structure can extend parallel to the lateral direction. The ridge structure and the further ridge structure can be arranged on a substrate of the laser device. The substrate can have a main plane of extension. The lateral direction can extend parallel to the main plane of extension of the substrate.

The further ridge structure can extend parallel to the lateral direction. A main extension direction of the further ridge structure can extend parallel to the lateral direction. This can mean, that the ridge structure and the further ridge structure extend parallel to each other. The ridge structure and the further ridge structure can be arranged next to each other on the substrate. The ridge structure and the further ridge structure can be arranged in one plane that extends parallel to a main plane of extension of the laser device.

The ridge structure and the further ridge structure can comprise the same materials. This can mean, that the ridge structure and the further ridge structure have the same composition. It is also possible that the ridge structure and the further ridge structure have the same setup. The ridge structure and the further ridge structure can have the same size. The ridge structure and the further ridge structure can be produced in the same way.

A first side of the further ridge structure can be connectable with a further power source. The further power source can have the same features as the power source. The laser device can further comprise a further current source and a further sense circuitry that are connected with each other. The further current source can have the same features as the current source. The further sense circuitry can have the same features as the sense circuitry. A second side of the further ridge structure can be connectable with the further current source and the further sense circuitry. The laser device can comprise a further detection circuitry and the second side of the further ridge structure can be connectable with the further detection circuitry. The further detection circuitry can have the same features as the detection circuitry. Thus, it is possible to measure the temperature of for each ridge structure of the laser device. This advantageously enables to determine temperature gradients and/or hotspots within the laser device.

According to at least one embodiment of the laser device, the laser device comprises a detection circuitry and the second side of the ridge structure is connectable with the detection circuitry. The detection circuitry can be configured to readout signals received from the ridge structure. The detection circuitry can comprise sense electronics for analog processing or for digital processing with an ADC. That the second side is connectable with the detection circuitry can mean that it is possible to change between a state in which the second side is connected with the detection circuitry and a state in which the second side is disconnected from the detection circuitry. This can for example be achieved by connecting the second side with the detection circuitry via a switch, for example the second side switch. The detection circuitry can be configured to provide output signals. The detection circuitry can comprise a comparator.

The detection circuitry can advantageously be employed to monitor electromagnetic radiation emitted by another ridge structure of the laser device, for example by the further ridge structure. This is possible since there is a certain cross talk between the ridge structure and the further ridge structure. The cross talk can take place for example via the substrate, via a common layer on which the ridge structures are arranged or via at least one side wall of at least one of the ridges. This cross talk is used as a feedback. Once electromagnetic radiation is emitted by the further ridge structure, a part of this electromagnetic radiation also reaches the ridge structure where charge carriers are generated in response to this electromagnetic radiation. These charge carriers are converted into an electrical signal which can be either processed in analog or digital domain. In each case, the detection circuitry can be configured to provide an output signal that depends on the number of charge carriers generated in the ridge structure. The output signal provided by the detection circuitry can be employed for the calibration or monitoring of the emission of the further ridge structure. The output signal provided by the detection circuitry gives a measure for the intensity of laser radiation emitted by the further ridge structure. Thus, by monitoring the output signal, the intensity of laser radiation emitted by the further ridge structure can be monitored. This allows to adopt the power provided by a further power source to the further ridge structure in such a way that the intensity of the laser radiation emitted by the further ridge structure does not exceed a predefined threshold intensity.

The setup of the laser device has the advantage that no additional or external photodiode is required to monitor the emission of the further ridge structure. Instead, the ridge structure is employed for this purpose. As the further ridge structure can have the same setup as the ridge structure, the production process for the laser device is simplified.

Furthermore, no optical elements are required to direct laser radiation emitted by the ridge structures to a device that is configured to detect the laser radiation for monitoring. Instead, the cross talk between the ridge structure and the further ridge structure is used. In this way, the further ridge structure can be employed to monitor the intensity of laser radiation emitted by the ridge structure. Optical elements such as mirrors are not required in the setup of the laser device for directing radiation of the further ridge structure to the ridge structure. Consequently, the laser device can have a compact setup.

Another advantage of the laser device is that the ridge structure and the further ridge structure are arranged relatively close to each other. Therefore, the ridge structure and the further ridge structure have a similar temperature during operation. In this way, errors in monitoring the intensity of emitted laser radiation due to temperature differences are avoided or reduced. Furthermore, the ridge structure and the further ridge structure are exposed to the same environmental conditions. Thus, the ridge structure and the further ridge structure age in the same or a similar way. This enables to avoid or reduce errors in monitoring the intensity of the emitted radiation due to different aging effects. Since the ridges of the laser device are arranged close to each other the signal quality and the signal to noise ratio are improved.

In the same way as the ridge structure can be employed for monitoring the intensity of laser radiation emitted by the further ridge structure, the further ridge structure can be employed for monitoring the intensity of laser radiation emitted by the ridge structure. This means, an alternate operation of the ridge structure and the further ridge structure is possible. Both, the ridge structure and the further ridge structure, can be configured to emit laser radiation and both, the ridge structure and the further ridge structure, can be configured to detect radiation emitted by the other ridge structure due to cross talk. If the laser device comprises more than one ridge structure and/or more than one further ridge structure, at least two ridge structures can be employed for monitoring the intensity of laser radiation emitted by one or more of the other ridge structures. Employing at least two ridge structures for monitoring the intensity has the advantage, that the integration time is reduced in comparison to the case that only one ridge structure or a photodiode is employed for monitoring the intensity. A reduced integration time leads to a reduced time required for a calibration.

Employing several ridge structures within one laser device has the advantages that a simplified lens setup can be employed as the ridge structures are arranged close to each other, that the resolution is increased, that the production process is very similar for different ridge structures and that the temperature during operation is very similar for the different ridges.

According to at least one embodiment of the laser device, the ridge structure and the further ridge structure have the same size and the same shape. This has the advantage that the ridge structure and the further ridge structure can be produced in the same way. This simplifies the production of the laser device.

According to at least one embodiment of the laser device, the ridge structure and/or the further ridge structure is configured to generate charge carriers in response to exposure to electromagnetic radiation. The ridge structure and/or the further ridge structure can comprise a pn-junction. In an active region around the pn-junction charge carriers can be generated in response to exposure to electromagnetic radiation. This means, that the ridge structure and/or the further ridge structure can be configured to generate charge carriers once exposed to electromagnetic radiation. This enables, that the ridge structure and/or the further ridge structure can be employed for monitoring the intensity of electromagnetic radiation emitted by a respective other ridge structure.

According to at least one embodiment of the laser device, the ridge structure is configured to detect electromagnetic radiation emitted by the further ridge structure and the further ridge structure is configured to detect electromagnetic radiation emitted by the ridge structure. This can mean, that charge carriers are generated in the ridge structure in response to electromagnetic radiation emitted by the further ridge structure and reach the ridge structure. Generated charge carriers can be transferred to the detection circuitry. In this way, electromagnetic radiation emitted by the further ridge structure is detected by the ridge structure. Electromagnetic radiation emitted by the further ridge structure can be received by the ridge structure via cross talk. That the ridge structure is configured to detect electromagnetic radiation emitted by the further ridge structure has the advantage that the ridge structure can be employed to monitor the intensity of laser radiation emitted by the further ridge structure. Charge carriers can be generated in the further ridge structure in response to electromagnetic radiation emitted by the ridge structure and reach the further ridge structure. Generated charge carriers can be transferred to the further detection circuitry. In this way, electromagnetic radiation emitted by the ridge structure is detected by the further ridge structure. Electromagnetic radiation emitted by the ridge structure can be received by the further ridge structure via cross talk. That the further ridge structure is configured to detect electromagnetic radiation emitted by the ridge structure has the advantage that the further ridge structure can be employed to monitor the intensity of laser radiation emitted by the ridge structure.

According to at least one embodiment of the laser device, the ridge structure and the further ridge structure are monolithically integrated. The ridge structure and the further ridge structure can for example be formed on the same substrate. That the ridge structure and the further ridge structure are monolithically integrated has the advantage that the ridge structure and the further ridge structure are arranged close enough to each other so that electromagnetic radiation emitted by the ridge structure can reach the further ridge structure via cross talk and vice versa. This allows to employ one of the ridge structures for monitoring the intensity of radiation emitted by the other ridge structure.

At least one further ridge structure of the laser device can be a dummy ridge structure. The dummy ridge structure is arranged closer to a side surface of the laser device than the ridge structure. It is possible that the dummy ridge structure is not employed for the emission of laser radiation. However, it is possible that the dummy ridge structure is employed for measuring the temperature of the dummy ridge structure and/or for detecting electromagnetic radiation emitted by the ridge structure or one of the ridge structures of the laser device.

Furthermore, a method for operating a laser device is provided. The laser device can preferably be operated by the method for operating a laser device described herein. This means all features disclosed for the laser device are also disclosed for the method for operating a laser device and vice-versa.

According to at least one embodiment of the method for operating a laser device, the method comprises connecting a first side of a ridge structure of the laser device with a power source and providing the ridge structure with power by the power source so that laser radiation is emitted by the ridge structure. The first side can be connected with the power source by closing a first side switch arranged between the first side of the ridge structure and the power source. The ridge structure can be provided with a positive current by the power source.

According to at least one embodiment of the method for operating a laser device, the method comprises disconnecting the first side from the power source. The first side can be disconnected from the power source by opening the first side switch or by connecting the first side with a component different from the power source via the first side switch.

According to at least one embodiment of the method for operating a laser device, the method comprises connecting a second side of the ridge structure with a current source of the laser device and with a sense circuitry of the laser device and providing the ridge structure with a predefined current by the current source. The second side can be connected with the current source and the sense circuitry by closing a second side switch arranged between on the one side the second side and on the other side the current source and the sense circuitry. The ridge structure can be provided with a predefined negative current by the current source.

According to at least one embodiment of the method for operating a laser device, the method comprises measuring the voltage across the ridge structure with the sense circuitry. The voltage across the ridge structure can be measured with the sense circuitry at the same time that a predefined current is provided to the ridge structure by the current source.

According to at least one embodiment of the method for operating a laser device, the current source and the sense circuitry are connected with each other.

According to at least one embodiment of the method for operating a laser device, the method comprises connecting a first side of a ridge structure of the laser device with a power source and providing the ridge structure with power by the power source so that laser radiation is emitted by the ridge structure, disconnecting the first side from the power source, connecting a second side of the ridge structure with a current source of the laser device and with a sense circuitry of the laser device and providing the ridge structure with a predefined current by the current source, and measuring the voltage across the ridge structure with the sense circuitry, wherein the current source and the sense circuitry are connected with each other.

The method for operating a laser device has the advantage that the ridge structure can be employed both for the emission of laser radiation and for measuring the temperature of the ridge structure. An additional or external temperature sensor or thermistor is not required. Thus, the laser device can have a compact setup.

According to at least one embodiment of the method for operating a laser device, the second side is disconnected from the current source and the sense circuitry while the first side is connected with the power source. This means, the temperature of the ridge structure is not measured while the ridge structure emits laser radiation. In other words, the temperature of the ridge structure is the measured when the ridge structure is not emitting laser radiation.

According to at least one embodiment of the method for operating a laser device, the voltage across the ridge structure during the connection with the power source has a polarity that is inverse in comparison to the polarity of the voltage across the ridge structure during the connection with the current source. The ridge structure can be forward biased during the connection with the power source. This can mean, that a positive voltage is applied to the ridge structure during the connection with the power source. During the connection with the power source means that the first side is connected with the power source. The ridge structure can be reversed biased during the connection with the current source. This can mean, that a negative voltage is applied to the ridge structure during the connection with the current source. During the connection with the current source means that the second side is connected with the current source. These two different modes of operation, forward bias operation and reverse bias operation, enable that the ridge structure is employed for both the emission of laser radiation and the measurement of the temperature of the ridge structure.

According to at least one embodiment of the method for operating a laser device, the ridge structure is connected with the current source during a time that is not employed for imaging in an imaging process. An imaging process can be a process where an image is projected by the laser device. The image can for example be projected by scanning over an area. Times that are not employed for imaging can be times where no part of the image is provided by the laser device. This can for example be dark times. Another example are the times during which optical elements of the laser device change their direction of movement. These optical elements can be mirrors for projecting the emitted laser radiation. These optical elements require time to change their direction of movement in the projection process. This time is usually not employed to project the image. Therefore, this time can be employed for measuring the temperature of the ridge structure. This can mean, that during this time that is not employed for imaging the ridge structure is connected with the current source. Thus, the time during the imaging process is used efficiently.

According to at least one embodiment of the method for operating a laser device, the method further comprises connecting the second side of the ridge structure with a detection circuitry that is configured to collect charge carriers generated in the ridge structure in response to exposure to electromagnetic radiation. During the time that the second side is connected with the detection circuitry, the first side can be connected with a ground potential. The ridge structure can be connected with the detection circuitry during a time within which a further ridge structure of the laser device emits laser radiation. Thus, the detection circuitry is employed to monitor the intensity of laser radiation emitted by the further ridge structure. During the time that the second side is connected with the detection circuitry, the second side can be disconnected from the sense circuitry and the current source. During the time that the second side is connected with the detection circuitry, the first side can be disconnected from the power source. Advantageously, no additional or external photo diode is required to monitor the intensity of laser radiation emitted by the further ridge structure. The further ridge structure can be employed in the same way as the ridge structure for monitoring the intensity of laser radiation emitted by the ridge structure.

According to at least one embodiment of the method for operating a laser device, charge carriers generated in the ridge structure are transferred to the detection circuitry at the same time as laser radiation is emitted by a further ridge structure of the laser device. This can mean, that a first side of the further ridge structure is connected with a further power source at the same time as the second side of the ridge structure is connected with the detection circuitry. Advantageously, the ridge structure can be employed for monitoring the intensity of laser radiation emitted by the further ridge structure.

According to at least one embodiment of the method for operating a laser device, the transfer of the charge carriers to the detection circuitry takes place at a time that is not employed for imaging in an imaging process. During the time that is not employed for imaging, the laser device can emit laser radiation. This laser radiation can be employed for the monitoring or calibration process. This means, the ridge structure detects electromagnetic radiation emitted by the further ridge structure during a time that is not employed for imaging in the imaging process. The ridge structure can detect electromagnetic radiation emitted by the further ridge structure during the whole time that is not employed for imaging in the imaging process or during at least one time frame within the time that is not employed for imaging in the imaging process. Therefore, the time that cannot be employed for imaging in the imaging process can advantageously be employed for monitoring the intensity of laser radiation emitted by the further ridge structure. In the same way, the further ridge structure can be employed for monitoring the intensity of laser radiation emitted by the ridge structure during a time that is not employed for imaging in the imaging process.

According to at least one embodiment of the method for operating a laser device, the second side of the ridge structure is connected with the sense circuitry at the same time as the second side of the further ridge structure is connected with the further sense circuitry. This can mean, that advantageously for the ridge structure and the further ridge structure or for all ridge structures of the laser device the temperatures of the ridge structures are measured at the same time.

### BRIEF DESCRIPTION OF THE DRAWINGS

The following description of figures may further illustrate and explain exemplary embodiments. Components that are functionally identical or have an identical effect are denoted by identical references. Identical or effectively identical components might be described only with respect to the figures where they occur first. Their description is not necessarily repeated in successive figures.

FIG. 1 shows a part of an exemplary embodiment of the laser device.

FIG. 2 shows an exemplary embodiment of the laser device. With FIG. 2 also an exemplary embodiment of the method for operating a laser device is described.

With FIGS. 3 and 4 an exemplary embodiment of a sense circuitry is described.

FIG. 5 shows a part of another exemplary embodiment of the laser device.

With FIGS. 6 and 7 an exemplary embodiment of a detection circuitry is described.

FIG. 8 shows a part of another exemplary embodiment of the laser device.

With FIGS. 9, 10 and 11 another exemplary embodiment of the laser device and another exemplary embodiment of the method for operating a laser device are described.

### DETAILED DESCRIPTION

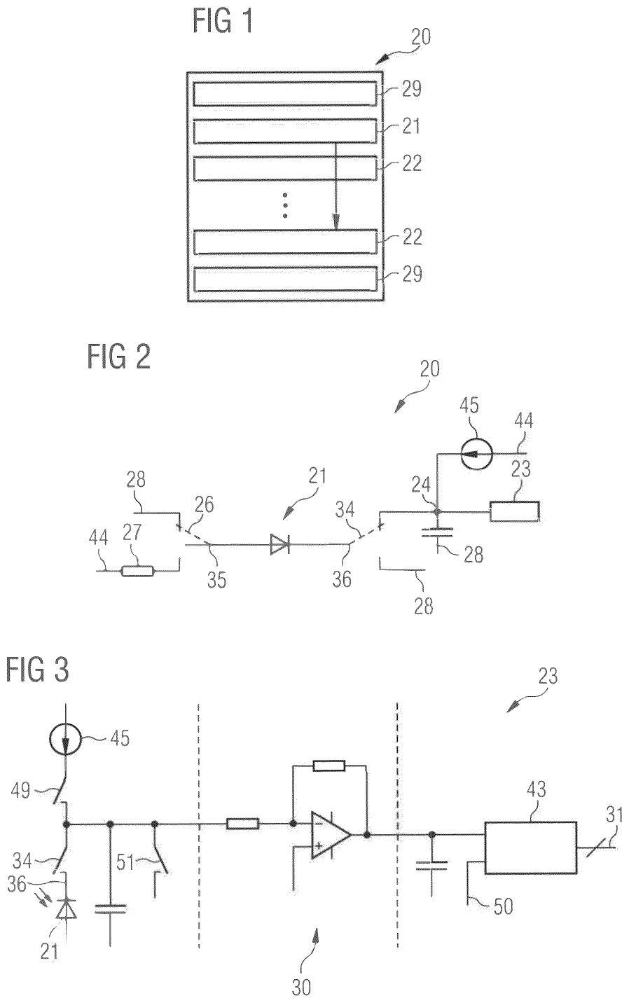

FIG. 1 shows a part of exemplary embodiment of a laser device 20. The laser device 20 comprises a ridge structure 21, two dummy ridge structures 29 and at least two further ridge structures 22. That the laser device 20 can comprise more than two further ridge structures 22 is shown by the dots between the further ridge structures 22. All ridge structures 21 of the laser device 20 are arranged next to each other. This means, FIG. 1 shows a top view on the laser device 20. The two ridge structures 21 at the sides are each a dummy ridge structure 29. The ridge structure 21 and the further ridge structures 22 can be arranged in any way between the two dummy ridge structures 29. The ridge structure 21 and the further ridge structures 22 can have the same features. The dummy ridge structures 29 can have the same size and can comprise the same materials as the ridge structure 21.

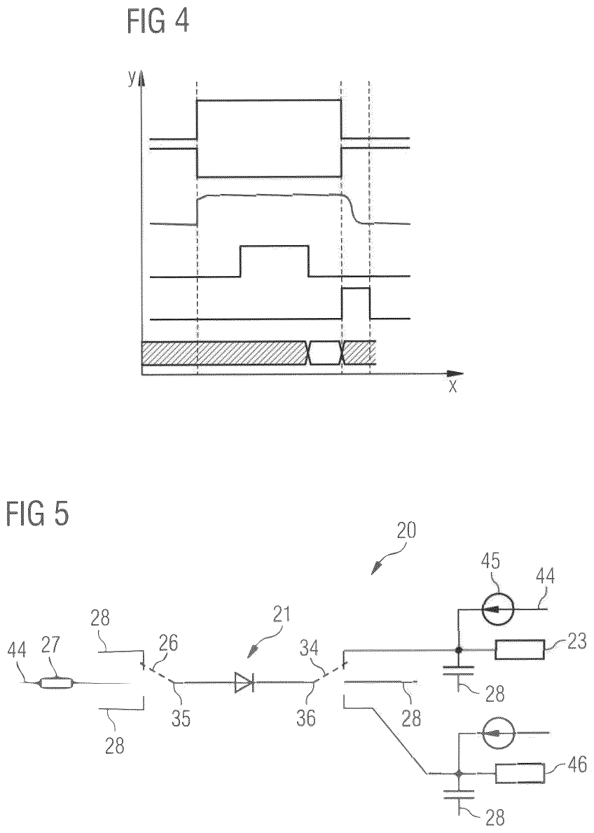

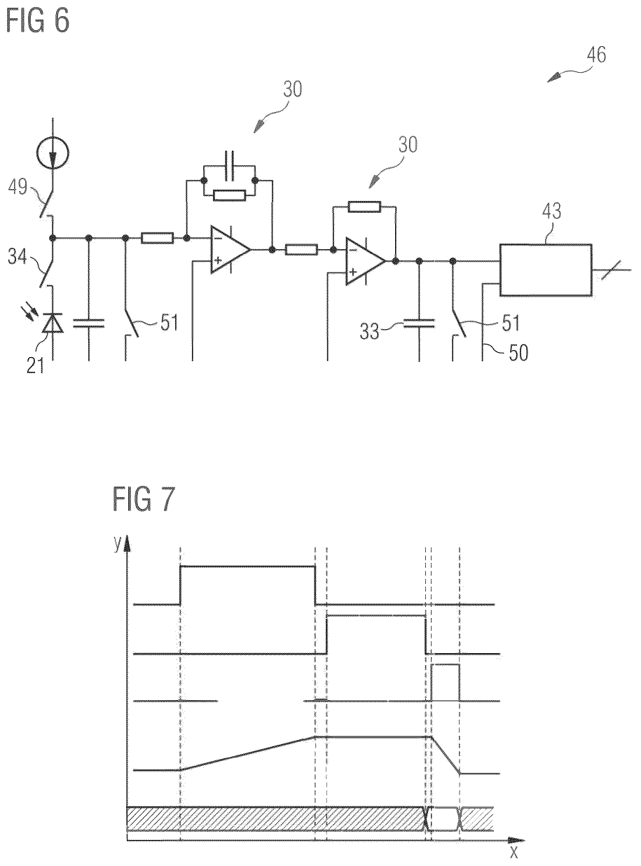

FIG. 2 shows an exemplary embodiment of the laser device 20. The laser device 20 comprises at least one ridge structure 21 that is configured to emit laser radiation. The ridge structure 21 has a first side 35 and a second side 36. At the first side 35 a first side switch 26 is arranged. The laser device 20 further comprises a power source 27. The first side 35 is connectable with the power source 27 via the first side switch 26. The first side 35 is also connectable with a ground potential 28 via the first side switch 26. The power source 27 is arranged between the first side switch 26 and a supply potential 44.

The laser device 20 further comprises a sense circuitry 23 and a current source 45 that are connected with each other. The sense circuitry 23 is configured to measure a voltage. For example, the sense circuitry 23 is configured to measure the voltage across the ridge structure 21. The second side 36 is connectable with the current source 45 and the sense circuitry 23 via a second side switch 34. The current source 45 and the sense circuitry 23 can be connected with a circuit node 24. The second side switch 34 can be arranged between the second side 36 and the circuit node 24. The current source 45 is connected in parallel to the ridge structure 21. The current source 45 is arranged between a supply potential 44 and the circuit node 24. The circuit node 24 is also connected with a ground potential 28. The second side 36 is connectable to a ground potential 28 via the second side switch 34. The ridge structure 21 comprises a pn-junction whose forward direction is from the first side 35 to the second side 36.

With FIG. 2 an exemplary embodiment of the method for operating a laser device 20 is described. According to the method the first side 35 of the ridge structure 21 is connected with the power source 27 by closing the first side switch 26 between the first side 35 and the power source 27. Thus, the ridge structure 21 is provided with power by the power source 27 so that laser radiation is emitted by the ridge structure 21. At the same time, the second side 36 of the ridge structure 21 is connected with a ground potential 28 via the second side switch 34. This means, the second side switch 34 is closed between the second side 36 and the ground potential 28. The second side 36 is disconnected from the current source 45 and the sense circuitry 23 while the first side 35 is connected with the power source 27.

In a next step, the first side 35 is disconnected from the power source 27. This is achieved by opening the first side switch 26. The first side 35 is connected with a ground potential 28. Furthermore, the second side 36 of the ridge structure 21 is connected with the current source 45 and the sense circuitry 23 by closing the second side switch 34 between the second side 36 and the circuit node 24. Thus, the ridge structure 21 is provided with a predefined current by the current source 45. At the same time, the voltage across the ridge structure 21 is measured with the sense circuitry 23. As the measured voltage is proportional to the temperature of the ridge structure 21, the temperature of the ridge structure 21 can be determined.

The voltage across the ridge structure 21 during the connection with the power source 27 has a polarity that is inverse in comparison to the polarity of the voltage across the ridge structure 21 during the connection with the current source 45.

FIG. 3 shows an exemplary embodiment of the sense circuitry 23. The sense circuitry 23 is connected with the second side 36 of the ridge structure 21 via the second side switch 34. The sense circuitry 23 comprises an amplifier 30 and an ADC 43. The sense circuitry 23 further comprises an output 31 where an output 31 signal can be provided. The sense circuitry 23 further comprises a first switch 49, a second switch 50 and a third switch 51. The current source 45 is connected with the sense circuitry 23.

With the diagram shown in FIG. 4 it is described how the sense circuitry 23 can be operated. On the x-axis the time is plotted. On the y-axis different signals are plotted. In the top line, the state of the first switch 49 and the second side switch 34 are plotted. For each switch, the low signal relates to the switch being open and the high signal relates to the switch being closed. Once the first switch 49 and the second side switch 34 are closed, the signal acquisition starts. Once the first switch 49 and the second side switch 34 are open again, a reset phase starts. The second line in the diagram shows the current level provided by the current source 45. The third line shows the voltage level at the ADC 43. The fourth line shows the state of the second switch 50 and the fifth line shows the state of the third switch 51. The bottom line shows when data is acquired, namely in the region that is not marked with dashed lines.

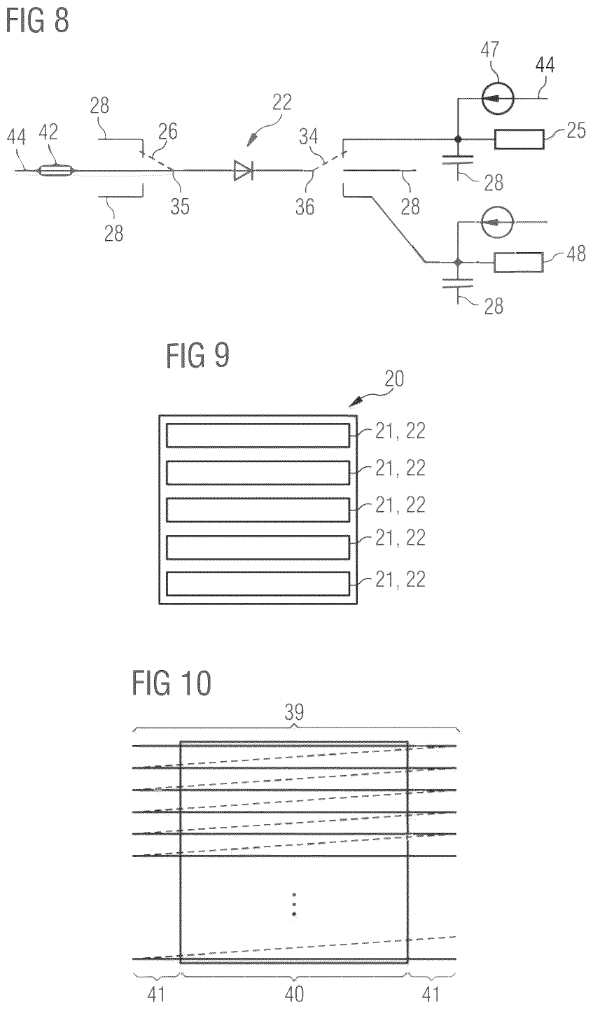

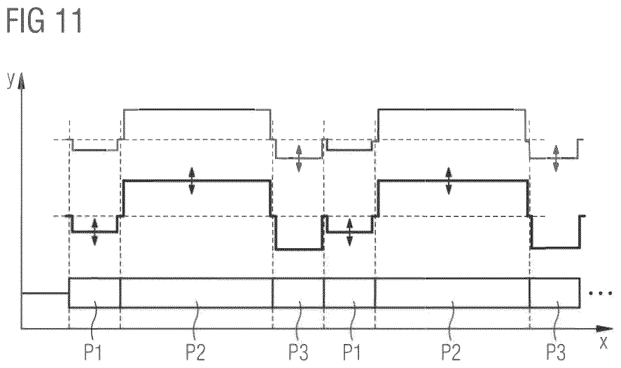

FIG. 5 shows a part of another exemplary embodiment of the laser device 20. In comparison to the embodiment shown in FIG. 2, laser device 20 further comprises at least one further ridge structure 22. The further ridge structure 22 can have the same features as the ridge structure 21. For example, the ridge structure 21 and the further ridge structure 22 can have the same size and shape. An exemplary embodiment of the further ridge structure 22 is shown in FIG. 8.

In addition to the components of the laser device 20 shown in FIG. 2, the embodiment of FIG. 5 comprises a detection circuitry 46, wherein the second side 36 of the ridge structure 21 is connectable with the detection circuitry 46. The second side 36 is connectable with the detection circuitry 46 via the second side switch 34. The detection circuitry 46 is connected with a ground potential 28. This means, the second side switch 34 has three different closed positions. Also the first side switch 26 has three different closed positions. Once the second side switch 34 connects the second side 36 with the detection circuitry 46, the first side 35 is connected with a ground potential 28 via the first side switch 26.

The ridge structure 21 is configured to generate charge carriers in response to exposure to electromagnetic radiation. Thus, the ridge structure 21 is configured to detect electromagnetic radiation emitted by the further ridge structure 22. The further ridge structure 22 can be arranged adjacent to the ridge structure 21, as for example shown in FIG. 1. The ridge structure 21 and the further ridge structure 22 are monolithically integrated.

In another step of the method, the second side 36 of the ridge structure 21 is connected with the detection circuitry 46 that is configured to collect charge carriers generated in the ridge structure 21 in response to exposure to electromagnetic radiation. Charge carriers generated in the ridge structure 21 are transferred to the detection circuitry 46 at the same time as laser radiation is emitted by the further ridge structure 22.

FIG. 6 shows an exemplary embodiment of the detection circuitry 46. The further detection circuitry 48 can have the same setup as the detection circuitry 46. The detection circuitry 46 is connected with the ridge structure 21 to which a voltage is applied. The detection circuitry 46 comprises two amplifiers 30, a hold capacitor 33, an ADC 43, first switches 49, a second switch 50 and third switches 51. The detection circuitry 46 is configured to process the received signals in the digital domain. The detection circuitry 46 is configured to measure the current that flows from the ridge structure 21 to the detection circuitry 46. The measured current is proportional to the intensity of electromagnetic radiation reaching the ridge structure 21.

FIG. 7 shows a time diagram for the operation of the detection circuitry 46 shown in FIG. 6. On the x-axis the time is plotted. On the y-axis different parameters are plotted on top of each other. In the top line in the diagram the state of the first switch 49 is plotted. For each switch, the high value relates to the switch being closed and the low value relates to the switch being open. In the second line in the diagram the state of the second switch 50 is plotted. In the third line in the diagram the state of the third switch 51 is plotted. In the fourth line in the diagram the voltage at the hold capacitor 33 is plotted. In the last line in the diagram it is plotted when an output 31 value is provided by the detection circuitry 46. This is the case after an integration time and a hold-and-convert time. The time when output 31 values are provided by the detection circuitry 46 is marked as the region that is not marked with dashed lines. FIG. 8 shows another part of the exemplary embodiment of the laser device 20 of FIG. 5. FIG. 8 shows the connection of the further ridge structure 22. The setup around the further ridge structure 22 is the same as for the ridge structure 21, as shown in FIG. 5. The only difference is, that for the further ridge structure 22 not the same power source 27, current source 45, sense circuitry 23 and detection circuitry 46 are employed as for the ridge structure 21. Thus, the first side 35 of the further ridge structure 22 is connectable with a further power source 42 via a first side switch 26. The second side 36 of the further ridge structure 22 is connectable with a further current source 47 and a further sense circuitry 25 via a second side switch 34. The second side 36 of the further ridge structure 22 is also connectable with a further detection circuitry 48 via the second side switch 34.

The further ridge structure 22 is configured to generate charge carriers in response to exposure to electromagnetic radiation. Thus, the further ridge structure 22 is configured to detect electromagnetic radiation emitted by the ridge structure 21.

With FIGS. 9, 10 and 11 another exemplary embodiment of the laser device 20 and another exemplary embodiment of the method for operating a laser device 20 are described. FIG. 9 shows another exemplary embodiment of the laser device 20. The laser device 20 comprises five ridge structures 21, 22 that are arranged as shown in FIG. 1. The ridge structures 21 are each either a ridge structure 21 or a further ridge structure 22.

With FIG. 10 it is described how the laser device 20 of FIG. 9 can be operated. One ridge structure 21, 22 or more than one ridge structure 21, 22 at a time is employed to project a part of an image 40 into a projection area 39. For this purpose, the laser radiation emitted by the ridge structures 21, 22 is deflected by optical elements such as a mirror according to a projection pattern. As an example, FIG. 10 shows a linear projection pattern. However, also other projection patterns are possible. For each row of the image 40 the optical elements require some time to change their direction of movement. Therefore, the image 40 provided is a smaller than the projection area 39. This leads to areas of the projection area 39 that are not employed for projecting the image 40. These areas are arranged at two sides of the projection area 39 and are referred to as overshoot regions 41. The basic idea of this embodiment is that these overshoot regions 41 are employed for temperature measurements and monitoring the intensity of emitted laser radiation.

During the measurement of the temperature, it is necessary that none of the ridge structures 21, 22 emits laser radiation. Therefore, the measurement of the temperature can be carried out for all ridge structures 21, 22 at the same time. The temperature of the ridge structures 21, 22 can be measured for example within one of the overshoot regions 41 for each line of the image 40. As the overshoot regions 41 are not required for forming the image 40, this time can be used to monitor the temperature of the ridge structures 21, 22.

Furthermore, the overshoot regions 41 can be employed to monitor the intensity of emitted laser radiation. During the time that laser radiation is emitted in at least one overshoot region 41 by one ridge structure 21, 22, the remaining ridge structures 21, 22 can be employed to monitor the emitted laser radiation. Therefore, this time that is not required for projecting the image 40 is efficiently used for monitoring or calibrating the emitted laser radiation. The detection of emitted electromagnetic radiation can take place during the emission of laser radiation into at least one of the overshoot regions 41 or into more than one overshoot region 41. The detection of emitted electromagnetic radiation can take place during the emission of laser radiation into the overshoot regions 41 arranged at one side of the image 40 or into all overshoot regions 41. At least one ridge structure 21, 22 that is not employed for the emission of laser radiation or more than one ridge structure 21, 22 that is not employed for the emission of laser radiation or all ridge structures 21, 22 that are not employed for the emission of laser radiation can be employed for the detection of electromagnetic radiation. Each ridge structure 21, 22 can be employed for both the emission of laser radiation and the detection of electromagnetic radiation. The monitoring or calibration of a ridge structure 21, 22 can take place for only one of the overshoot regions 41, only for the other one of the overshoot regions 41 or for both overshoot regions 41. For the detection of electromagnetic radiation, all ridge structures 21, 22 that are employed for the detection can be connected with the same detection circuitry 46. Thus, the current increases which reduces the required integration time. Therefore, as more than one, in the example of FIG. 10 four, ridge structures 21, 22 are employed for the detection of electromagnetic radiation, the time required for the monitoring or calibration is reduced.

With FIG. 11 the different modes of operation of the embodiment of the laser device 20 of FIG. 9 are described. On the x-axis the time is plotted and on the y-axis different signals are plotted. In the top line of the diagram the current through the ridge structure 21 is plotted. In the second line the voltage across the ridge structure 21 is plotted. In a first phase P1 the temperature of the ridge structure 21 is measured. Therefore, the first side 35 is connected with a ground potential 28 and the second side 36 is connected with the current source 45 and the sensor circuitry. A negative current is provided to the ridge structure 21 by the current source 45. Thus, also the voltage across the ridge structure 21 is negative. In a second phase P2, laser radiation is emitted. Therefore, the first side 35 is connected with the power source 27 and the second side 36 is connected with a ground potential 28. The power source 27 provides a positive current to the ridge structure 21. Thus, also the voltage across the ridge structure 21 is positive. In a third phase P3 electromagnetic radiation emitted by one further ridge structure 22 is detected by the ridge structure 21. Therefore, the first side 35 is connected with a ground potential 28 and the second side 36 connected with the detection circuitry 46. A negative bias is applied to the ridge structure 21 and the current reaching the detection circuitry 46 is measured. The first phase P1 and the third phase P3 can be carried out in overshoot regions 41. In the second phase P2 a part of the image 40 can be projected. After the third phase P3, the first phase P1 starts again.

It will be appreciated that the disclosure is not limited to the disclosed embodiments and to what has been particularly shown and described hereinabove. Rather, features recited in separate dependent claims or in the description may advantageously be combined. Furthermore, the scope of the disclosure includes those variations and modifications, which will be apparent to those skilled in the art. The term “comprising”, insofar it was used in the claims or in the description, does not exclude other elements or steps of a corresponding feature or procedure. In case that the terms “a” or “an” were used in conjunction with features, they do not exclude a plurality of such features. Moreover, any reference signs in the claims should not be construed as limiting the scope.

1. A laser device comprising:
at least one ridge structure that is configured to emit laser radiation, a sense circuitry,
a power source, and
a current source, wherein
the ridge structure has a first side and a second side,
the first side is connectable with the power source,
the current source and the sense circuitry are connected with each other,
the second side is connectable with the current source and the sense circuitry
the power source is configured to provide a positive current, and
the current source is configured to provide a negative current.

2. The laser device according to claim 1, wherein the sense circuitry is configured to measure a voltage.

3. The laser device according to claim 1, wherein the first side is connectable with the power source via a first side switch.

4. The laser device according to claim 1, wherein a second side switch is arranged between the second side and a circuit node with which the current source and the sense circuitry are connected.

5. The laser baser device according to claim 1, wherein the ridge structure comprises a pn-junction whose forward direction is from the first side to the second side.

6. The laser device according to claim 1, wherein the first side and/or the second side is connectable to a ground potential.

7. The laser device according to claim 1, wherein the laser device comprises at least one further ridge structure.

8. The laser device according to claim 7, wherein the laser device comprises a detection circuitry and wherein the second side of the ridge structure is connectable with the detection circuitry.

9. The laser device according to claim 7, wherein the ridge structure and the further ridge structure have the same size and the same shape.

10. The laser device according to claim 7, wherein the ridge structure and/or the further ridge structure is configured to generate charge carriers in response to exposure to electromagnetic radiation.

11. The laser device according to claim 7, wherein the ridge structure is configured to detect electromagnetic radiation emitted by the further ridge structure and the further ridge structure is configured to detect electromagnetic radiation emitted by the ridge structure.

12. The laser device according to claim 7, wherein the ridge structure and the further ridge structure are monolithically integrated.

13. A method for operating a laser device, the method comprising:
connecting a first side of a ridge structure of the laser device with a power source and providing the ridge structure with power by the power source so that laser radiation is emitted by the ridge structure,
disconnecting the first side from the power source,
connecting a second side of the ridge structure with a current source of the laser device and with a sense circuitry of the laser device and providing the ridge structure with a predefined current by the current source, and
measuring the voltage across the ridge structure with the sense circuitry, wherein
the current source and the sense circuitry are connected with each other.

14. The method for operating a laser device according to claim 13, wherein the second side is disconnected from the current source and the sense circuitry while the first side is connected with the power source.

15. The method for operating a laser device according to claim 13, wherein the voltage across the ridge structure during the connection with the power source has a polarity that is inverse in comparison to the polarity of the voltage across the ridge structure during the connection with the current source.

16. The method for operating a laser device according to claim 13, wherein the ridge structure is connected with the current source during a time that is not employed for imaging in an imaging process.

17. The method for operating a laser device according to claim 13, the method further comprising connecting the second side of the ridge structure with a detection circuitry that is configured to collect charge carriers generated in the ridge structure in response to exposure to electromagnetic radiation.

18. The method for operating a laser device according to claim 17, wherein charge carriers generated in the ridge structure are transferred to the detection circuitry at the same time as laser radiation is emitted by a further ridge structure of the laser device.

19. The method for operating a laser device according to claim 18, wherein the transfer of the charge carriers to the detection circuitry takes place at a time that is not employed for imaging in an imaging process.
